(19) United States
(12) Patent Application Publication
(10) Pub. No.: US 2026/0029474 A1
(43) Pub. Date: Jan. 29, 2026

(54) NON-DISRUPTIVE CONTROL UNIT BATTERY TEST

(71) Applicant: Johnson Controls Tyco IP Holdings LLP, Milwaukee, WI (US)

(72) Inventors: Alexandre GOUIN, Saints Basile le Grand, Quebec (CA); Daniel Paul CIANFROCCO, Clinton, MA (US)

(21) Appl. No.: 18/998,910

(22) PCT Filed: Aug. 1, 2023
(86) PCT No.: PCT/US2023/071413

§ 371 Date: Jan. 27, 2025

Related U.S. Application Data
(60) Provisional application No. 63/394,433, filed on Aug. 2, 2022.

(51) Int. Cl. G01R 31/371; G01R 31/3842

(52) U.S. Cl. CPC G01R 31/371; G01R 31/3842

(57) ABSTRACT

Example aspects include methods, apparatuses, and computer-readable medium for battery testing, including selecting, by a control unit of a system, an existing load configured in the system, wherein the existing load is connected to the control unit; and testing, by the control unit, a battery of the control unit by using the existing load to discharge the battery.

### CROSS-REFERENCE TO RELATED APPLICATION(S)

This application claims the benefit of U.S. Provisional Application No. 63/394,433, entitled “NON-DISRUPTIVE CONTROL UNIT BATTERY TEST” and filed on Aug. 2, 2022, which is expressly incorporated by reference herein in the entirety.

### BACKGROUND

The present disclosure relates generally to building automation/security/safety systems, and more particularly, to battery testing of a control unit in a building automation/security/safety system.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

An example implementation includes a method of battery testing, comprising selecting, by a control unit of a system, an existing load configured in the system, wherein the existing load is connected to the control unit. The method further includes testing, by the control unit, a battery of the control unit by using the existing load to discharge the battery.

Another example implementation includes an apparatus for battery testing. The apparatus comprises one or more processors and one or more memories communicatively coupled with the one or more processors and storing instructions, individually or in combination. The instructions, when executed by the one or more processors, individually or in combination, cause the one or more processors to select, by a control unit of a system, an existing load configured in the system, wherein the existing load is connected to the control unit. The instructions, when executed by the one or more processors, individually or in combination, further cause the one or more processors to test, by the control unit, a battery of the control unit by using the existing load to discharge the battery.

Another example implementation includes a computer-readable medium comprising instructions for battery testing. The instructions, when executed by one or more processors, individually or in combination, cause the one or more processors to select, by a control unit of a system, an existing load configured in the system, wherein the existing load is connected to the control unit. The instructions, when executed by the one or more processors, individually or in combination, further cause the one or more processors to test, by the control unit, a battery of the control unit by using the existing load to discharge the battery.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a schematic diagram of an example system including a control unit implementing battery test functionality, according to aspects of the present disclosure;

FIG. 2 is a schematic diagram of an example battery monitoring/charging system, according to aspects of the present disclosure;

FIGS. 3A-3D are schematic diagrams of a control unit including a single battery, according to aspects of the present disclosure;

FIGS. 4A-4C are schematic diagrams of a control unit including a pair of batteries, according to aspects of the present disclosure;

FIG. 5 is a flow diagram of an example method of selecting a load for battery testing, according to aspects of the present disclosure;

FIGS. 6A-6C include a flow diagram of an example method of using the load selected in the example method of FIG. 5 for battery testing, according to aspects of the present disclosure;

FIG. 7 is a block diagram of an example computing device which may implement a component in the example system of FIG. 1, according to aspects of the present disclosure; and

FIG. 8 is a flow diagram of an example method of battery testing, according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components may be shown in block diagram form in order to avoid obscuring such concepts.

Aspects of the present disclosure include apparatuses and methods of testing a battery of a control unit by using one or more existing loads that are connected to and/or configured within the control unit. Accordingly, the present aspects allow for a battery test without any new, supplementary load being added (e.g., without an external battery tester or resistor). Although some present aspects are described below with reference to a fire alarm control unit in a fire alarm system, the present aspects are not so limited and are applicable to any system having a control unit that includes a battery and is configured to supply power to one or more loads.

In some systems, such as but not limited to fire alarm systems, a control unit of the system may be powered by both an alternate current (AC) main and a backup battery, where the backup battery is used as a backup in case of an AC main outage. In these systems, the backup battery of the control unit needs to be periodically tested in order to ensure that the backup battery is operable to replace the AC power if needed. In some aspects, battery load tests and ohmic tests of the control unit may be configured according to a standard body, such as National Fire Protection Association (NFPA) 72, Underwriter Laboratories of Canada (ULC), etc. In some cases, a technician disconnects the battery from the control unit to test the battery. If the technician does not use a temporary battery to replace the battery that is being tested, the control unit runs solely on AC power during battery testing and has no backup capability in case a power outage happens.

In order to test the battery in the above systems, the technician connects the battery to a battery tester that applies a certain load for a certain time to discharge the battery, and then the battery voltage is measured to determine if the voltage is acceptable. If the voltage is lower than a certain level, the technician determines that the battery has failed and needs to be replaced. This process needs to be repeated for every battery in every cabinet in the system and may be cumbersome and time consuming due to the number of batteries that need to be tested. For example, the fire alarm system in a building may include a number of control units as well as a number of transponders (which extend the system), each including one or more batteries. In some aspects, for example, each transponder or control unit may be made of multiple adjacent cabinets, and those cabinets may share two batteries, or each cabinet may have two batteries. Further, if a battery is disconnected/removed for testing, the system is unable to sustain the normal operation or the fire alarm operation in case of a power outage. Additionally, a battery discharge time during testing may be, for example, up to several hours, which may require the technician to either stay at the control unit for that time or to travel back and forth between multiple control units, potentially leaving the control units without battery backup capability.

In order to address the above issues, some present aspects provide a battery testing functionality that may be performed by a control unit, in some cases autonomously, using existing loads in the system to discharge a battery at a pre-determined rate. Since the control unit is testing the battery using an existing load and the battery is not disconnected, the system is still operational to detect alarms, etc. In some aspects, if an alarm event is detected during battery testing, the control unit may abort battery testing and return to normal operation. In some aspects, the battery testing functionality provided by the control unit may also be requested remotely. For example, a technician may remotely request that all batteries of a system in a building be tested by one or more control units in the system. For example, the technician may connect a computer to a control unit in the system and request the battery test of all batteries in the system, so that the batteries in every cabinet in the system are tested within a period of time (e.g., 5 minutes, 3 hours, etc.). Alternatively, the technician may send the battery test request via a workstation or other device that is in networked communication with one or more control units in the system. In some aspects, in order to ensure system availability, the batteries may be tested one by one so that only one control unit is in testing status. Alternatively, multiple batteries may be tested simultaneously in order to reduce the total duration of battery testing in the system.

In some aspects, an analog to digital converter (ADC) in the control unit may be used to convert voltage/current measurements of a battery into digital values that are processed by the control unit for testing the battery.

In one non-limiting aspect, for example, an existing load/periphery that is used to test the battery of a control unit may be, but is not limited to, a sensor/detector (e.g., a smoke detector (e.g., a photo sensor, an ionization sensor, etc.), a heat sensor, a carbon monoxide (CO) sensor, a combination sensor, etc.), a speaker, a notification appliance (e.g., a visual alarm appliance (e.g., a strobe), an audio alarm appliance (e.g., a siren, a horn, etc.), another battery in the control unit, another battery in another control unit, etc. Alternatively or additionally, in some aspects, a load such as a resistor may be configured within a control unit (e.g., on an unused circuit such as an auxiliary power) and may be used for discharging and testing a battery in the control unit.

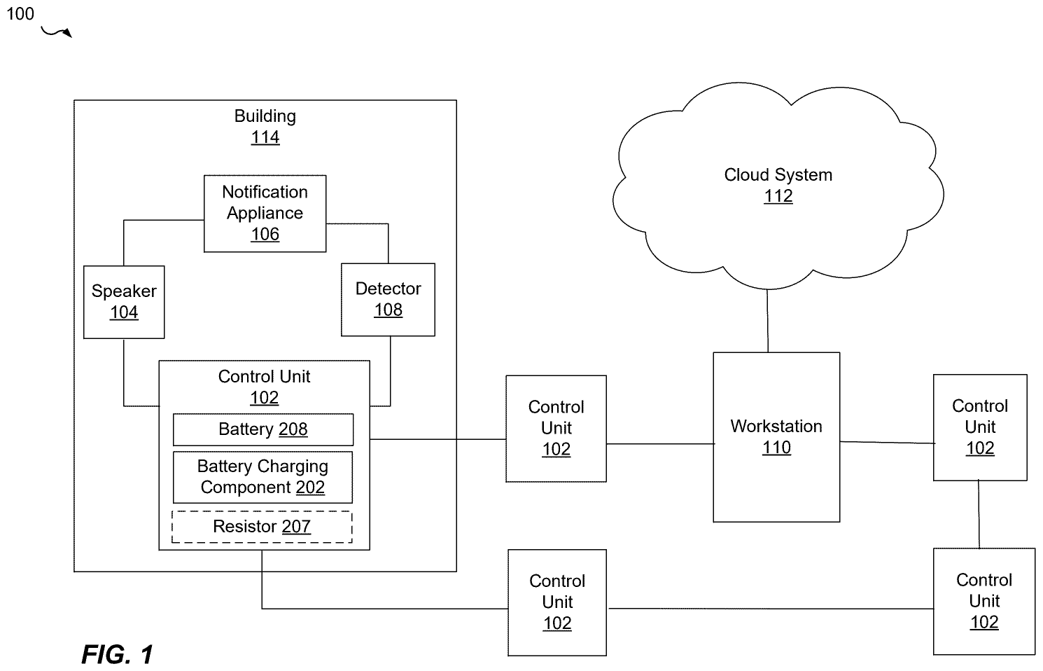

Referring to FIG. 1, in one non-limiting aspect, for example, a fire alarm system 100 may include one or more control units 102 that are in a networked connection with a workstation 110, which is connected to a cloud system 112. Each control unit 102 may be configured in a building 114 and may be connected to one or more fire alarm peripheral devices in the building 114, such as, for example, one or more speakers 102, notification appliances 106, detectors 108, etc.

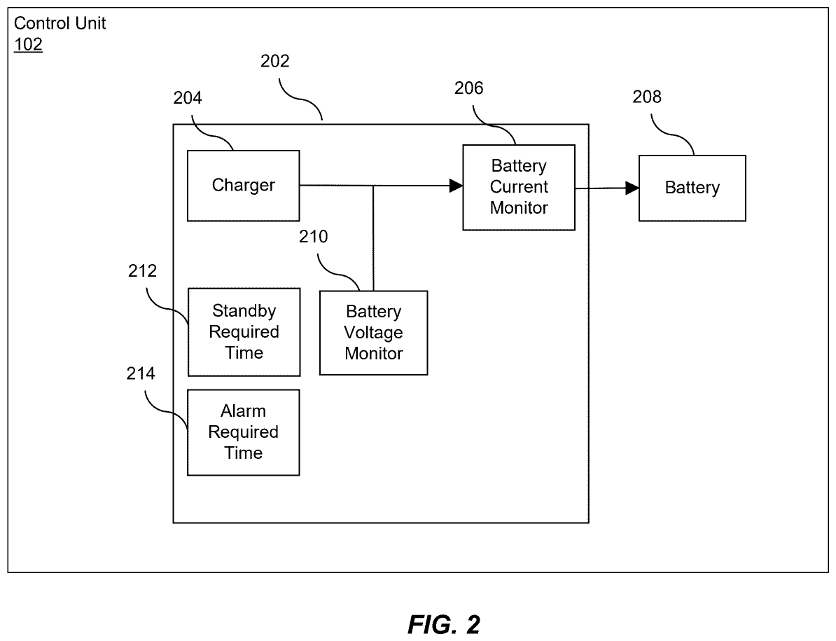

Referring to FIGS. 1 and 2, the control unit 102 may include a battery 208 and a battery charging component 202 configured to control the charge of the battery 208. The battery charging component 202 may include a charger 204, a battery current monitor 206, and a battery voltage monitor 210. Based on the measurements/readings of the battery current monitor 206 and the battery voltage monitor 210, the battery charging component 202 determines whether the battery 208 has sufficient draw capacity to support a standby required time 212 and/or an alarm required time 214.

In some present aspects, the control unit 102 implements dynamic loading and non-disruptive applications to conduct tests of the battery 208 using existing loads such as, but not limited to, the speaker 104, the notification appliance 106, the detector 108, or a built-in load such as a resistor 207 that is configured within the control panel 102 for battery testing. In some aspects, the control panel 102 may configure battery load tests and ohmic tests according to a standard body, such as NFPA 72, ULC, etc. In some aspects, for example, the control panel 102 may confirm a full charge of the battery 208 prior to starting a test of the battery 208. Then, the control panel 102 may conduct the test of the battery 208 without disconnection of the battery 208 from the control unit 102, and the test is configured to meet NFPA and ULC, in time ranges such as 5 minutes, 3 hours, etc. In some aspects, the battery test is fully automated and least disruptive.

In some aspects, for example, a test of the battery 208 may be manually started or may run automatically on a schedule. The control unit 102 may measure the standby and alarm draw as required to evaluate if the capacity of the battery 208 is sufficient.

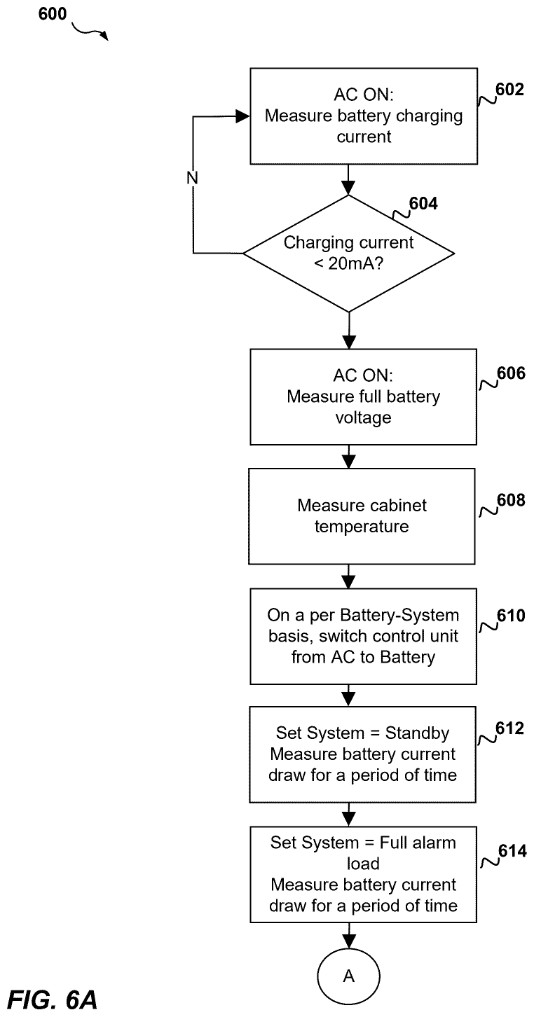

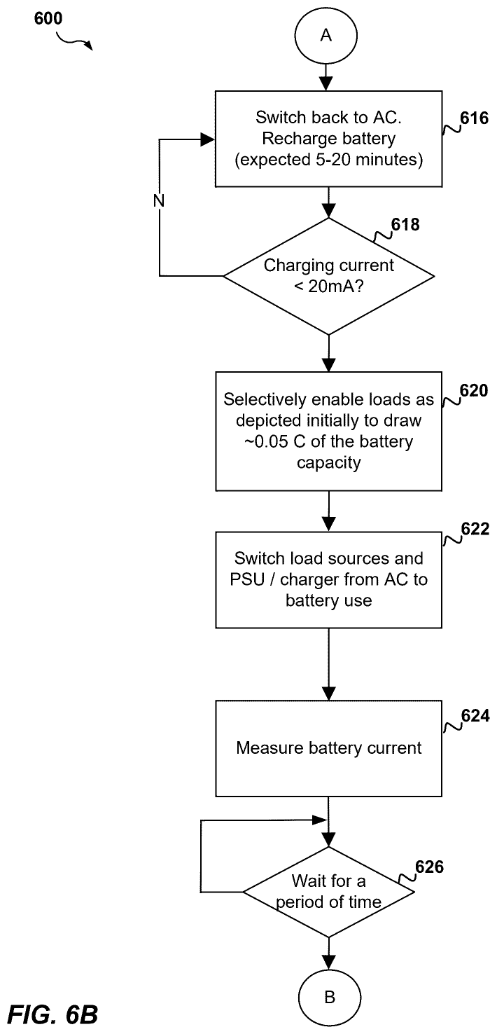

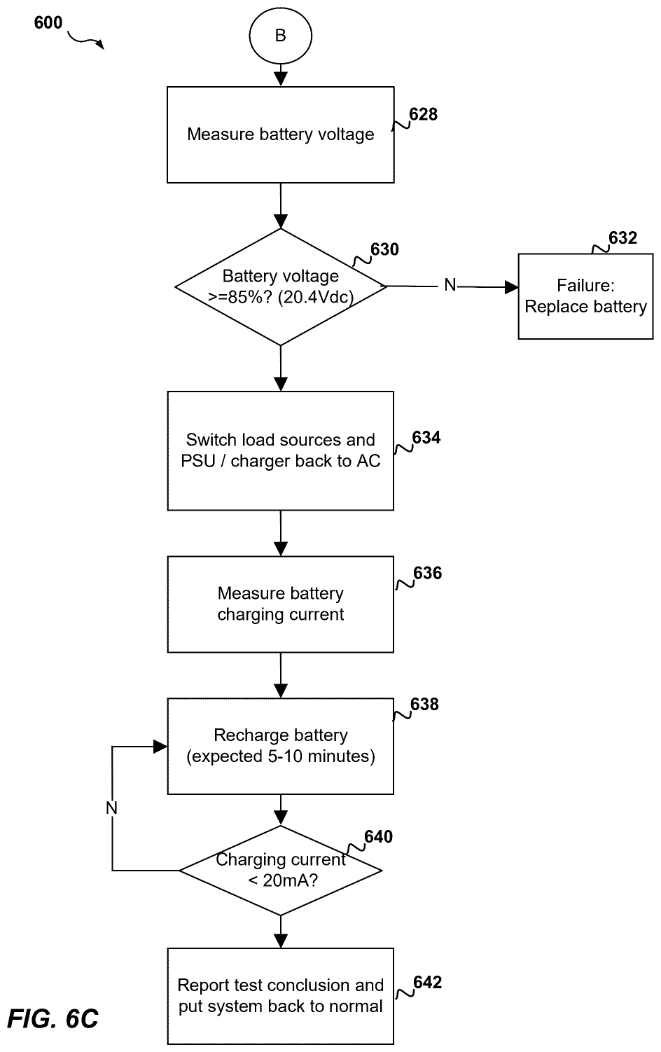

In some aspects, a specific current may be applied as a load by the control unit 102, where the current meets the battery test standards. Some present aspects only use silent battery testing loads on voice systems/horns/strobes/etc., by operating these devices at an inaudible frequency. In an aspect, for example, a main discharge path of the battery 208 during the test may be inaudible sounds played over one or more speakers 104 (e.g., with a frequency of greater than 20 kHz that is inaudible to humans). In some aspects, a backup for performing the test may be one or more audible notification appliances 106 such as one or more horns (also preferably using an inaudible sound with a frequency of greater than 20 kHz), and a third option may be one or more visual notification appliances 106 such as one or more strobes. In some aspects, since some verifications are already performed for loading (e.g., see FIGS. 6A-6C), in the case of a 5 minute test, the battery testing disrupts the system only slightly more, although silent testing is the preferred option. For example, if the system that is running off battery draws 1 A due to merely being connected, and a battery test requires 5 A, then an additional load that draws 4 A needs to be added to the system.

Additionally, some aspects cascade battery charge/discharges such that the testing load of one battery is recharging a previously-tested battery, and so on. For example, if multiple batteries 208 are present in the control unit 102 under test (e.g., multiple cabinets, multiple power supplies, multiple batteries, etc.), once a first iteration of testing has slightly depleted a first battery, the test of a second battery may be performed by using the necessary current to recharge the first battery as a discharge load for the second battery.

In some aspects, at the completion of the test, the control unit 102 may provide a report of the battery quality.

Accordingly, the present aspects obviate the need for an external battery tester and the need for connection/disconnection of batteries which would have reduced the life expectancy of the connectors. Further, by using a previously-tested battery as a battery test load or by operating speakers and/or horns at inaudible frequencies as a battery test load, the present aspects allow for silent testing of batteries in a control unit. Additionally, the present aspects allow for fully automated reports to be built into the control unit 102.

Some aspects allow for tests that are cascaded in time and use battery charge/discharges as silent loads for other batteries. Accordingly, for example, one pair of batteries may be tested at a given time in case a power outage happens. Alternatively, some aspects allow for testing a full site at once. For example, some aspects allow concurrent battery tests that require less technician time on site. For example, in one non-limiting aspect, tests for multiple nodes (e.g., 99 nodes) and multiple transponders (e.g., 99*31 transponders) may be started at the same time to reduce disruption.

Some aspects allow remote battery testing if permitted by the applicable testing standards. For example, in an aspect, battery tests may be performed remotely, for example, when a battery cabinet is difficult to access at the control unit 102 or when the control unit 102 (e.g., a network node or transponder) is in an area that is difficult to access.

In some aspects, the battery test calculations are done internally at the control unit 102, thus not requiring manual calculations.

In some aspects, if an alarm and/or power outage occurs during testing, although some batteries under test are slightly discharged, they are still attached and the control unit 102 cancels the test and recovers and resumes normal operations.

Some present aspects allow for the control unit 102 to perform the battery load test by dynamically adjusting the battery test load based on the test requirement rather than going full standby or full alarm. For example, the system may generally be either in standby, or in alarm where the load is greater. For battery testing, the present aspects select a load by turning on only a selection of system components, such as by controlling the charging current of a pre-depleted battery, by enabling a selected number of speakers, etc., as described herein with reference to various example aspects.

As compared to systems where an external battery tester is used to connect a load to a battery and measure the time and make the calculations, the battery testing functionality according to the present aspects reduces interruptions, saves time, may be autonomous, and may be remotely initiated. Further, the control unit 102 may keep trace of battery testing (e.g., keeps a log), and may self-restore to charging the battery 208 after the completion of the test. This would avoid some manual testing issues, such as a technician forgetting the batteries after a 3 hour test, a technician needing to be in front of the panel for a 3 hour test, etc. In some aspects, for example, the control unit 102 stops the battery test and returns to normal operation in case of a fire alarm or a power outage.

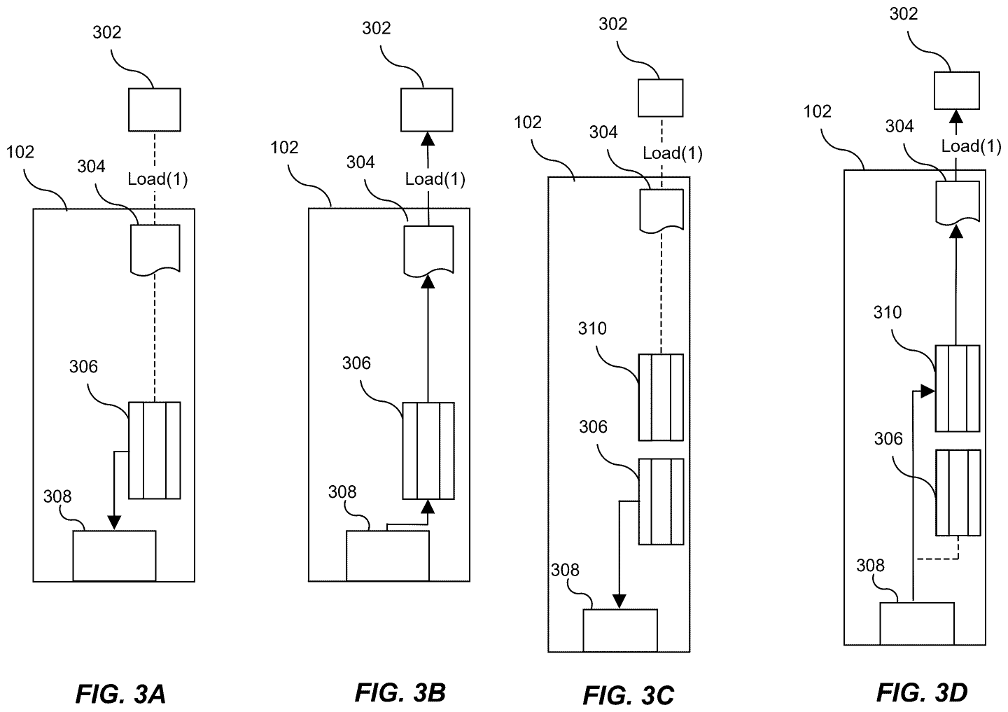

Referring to FIG. 3A, in some non-limiting example aspects, the enclosure of a control unit 102 may include a power supply unit (PSU)/charger 306, a battery 308, and an amplifier 304. The control unit 102 is connected with a load 302 and is configured for addressing, controlling, and/or supplying power to the load 302 to operate the load 302 as needed under normal operation. For example, under normal operation, the PSU/charger 306 may power the load 302 via the amplifier 304 to operate the load 302 as needed. The PSU/charger 306 is also configured for charging the battery 308 under normal operation.

However, referring to FIG. 3B, during battery testing, the battery 308 is connected to the load 302 via the PSU/charger 306 and the amplifier 304, so that the battery 308 may be discharged using the load 302. For example, in one non-limiting aspect, the battery 308 may be discharged at a C-rate of 0.05 C for 5 minutes using a 21 kHz speaker load (e.g., to generate an inaudible and non-disruptive sound). In some aspects, a C-rate of “kC” for a battery is defined as a discharge rate that would fully discharge the battery in “1/k” hours.

Referring to FIG. 3C, in some other non-limiting example aspects, in addition to the PSU/charger 306, the battery 308, and the amplifier 304, the enclosure of a control unit 102 may also include a PSU 310. In this case, under normal operation, the PSU/charger 306 is configured for charging the battery 308, while the PSU 310 powers the load 302 via the amplifier 304 as needed. However, referring to FIG. 3D, during battery testing, the battery 308 is connected to the load 302 via the PSU 310 and the amplifier 304, so that the battery 308 may be discharged using the load 302.

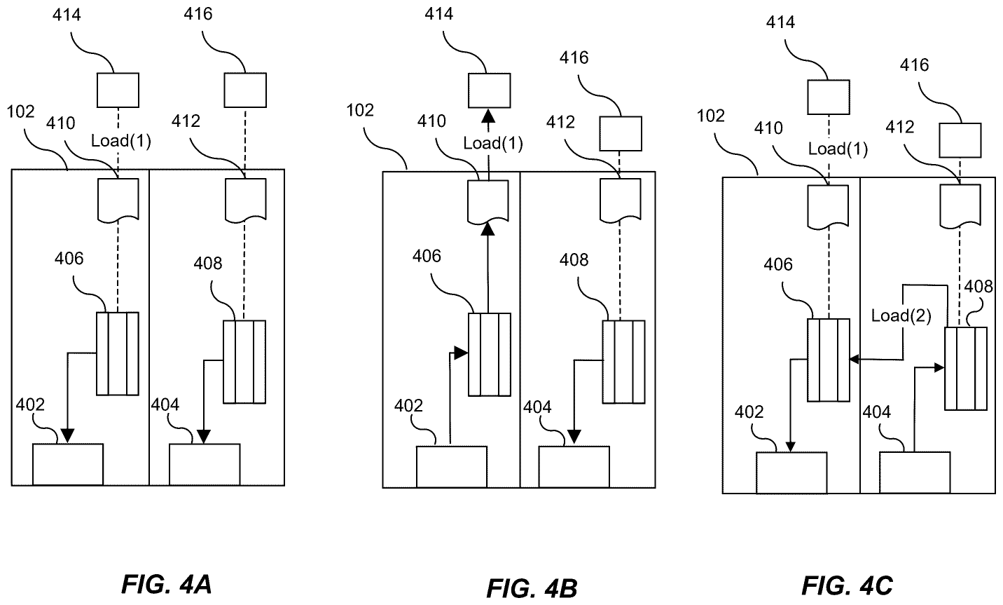

Referring to FIG. 4A, in some other non-limiting example aspects, the enclosure of a control unit 102 may include multiple sets of batteries, PSU/chargers, and amplifiers, where each set is configured for addressing, controlling, and/or supplying power to a respective load as needed under normal operation. In this case, the testing of the batteries may be cascaded in order to recharge a previously-tested battery by using that battery as a load for discharging the next battery to be tested.

Specifically, for example, a first PSU/charger 406 may power a first load 414 via a first amplifier 410 as needed during normal operation. The first PSU/charger 406 is also configured for charging a first battery 402 under normal operation. Further, a second PSU/charger 408 may power a second load 416 via a second amplifier 412 as needed during normal operation. The second PSU/charger 408 is also configured for charging a second battery 404 under normal operation.

However, referring to FIG. 4B, during battery testing, the first battery 402 is connected to the first load 414 via the first PSU/charger 406 and the first amplifier 410, so that the first battery 402 may be discharged using the first load 414, for example, at a C-rate of 0.05 C. Referring to FIG. 4C, after testing the first battery 402, the second battery 404 is tested by using the first battery 402 as a load to discharge the second battery 404. Specifically, the second battery 404 is connected to the first battery 402 by connecting the second PSU/charger 408 to the first PSU/charger 406, so that the second battery 404 is discharged onto the first battery 402, for example, at a C-rate of 0.05 C. This will also recharge the first battery 402 which has been discharged during the testing of the first battery 402.

Although the above aspects cascade the testing of two batteries 402, 404 that are in a same control unit 102, the present aspects are not so limited, and in some other aspects a battery in one control unit may be tested by using an already-tested battery in another control unit as a load to discharge onto.

Alternatively, in order to reduce the total testing time, the first battery 402 and the second battery 404 may be tested simultaneously, using the first load 414 and the second load 416, respectively.

In some aspects, if non-disruptive loads are not available for testing the batteries, the batteries may be tested using other loads during certain time periods that disruptions are minimal. For example, if speakers or horns that are operable at inaudible non-disruptive frequencies are not available at a building for battery testing, a strobe or other load may be used for battery testing during off-peak hours when the building is not crowded. In some other non-limiting aspects, for example, a visual notification appliance such as a light emitting diode (LED) strobe or xenon strobe may be used as a non-disruptive load for battery testing by operating the visual notification appliance in a specific manner, e.g., by supplying a continuous and low current to the visual notification appliance to avoid flashing lights, by operating the visual notification appliance at a dimmed state, etc.

In some aspects, the control unit 102 may collect battery test data/logs, and may send battery test reports to the workstation 110 to be uploaded to the cloud system 112 for presentation on one or more devices, such as a personal computer, a mobile phone, a remote control station, etc.

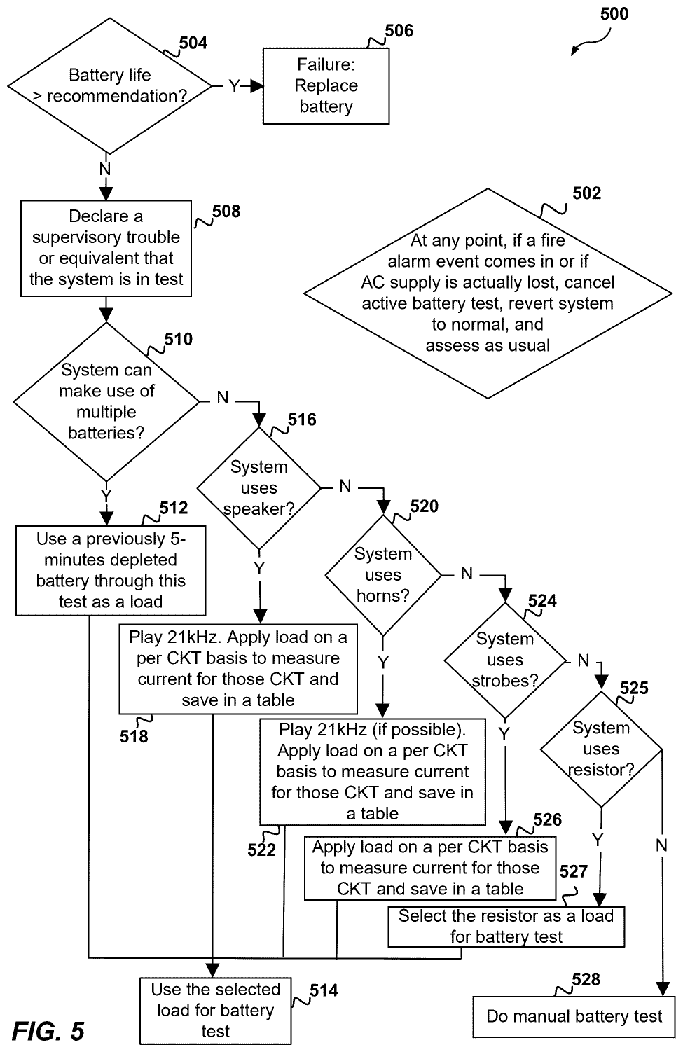

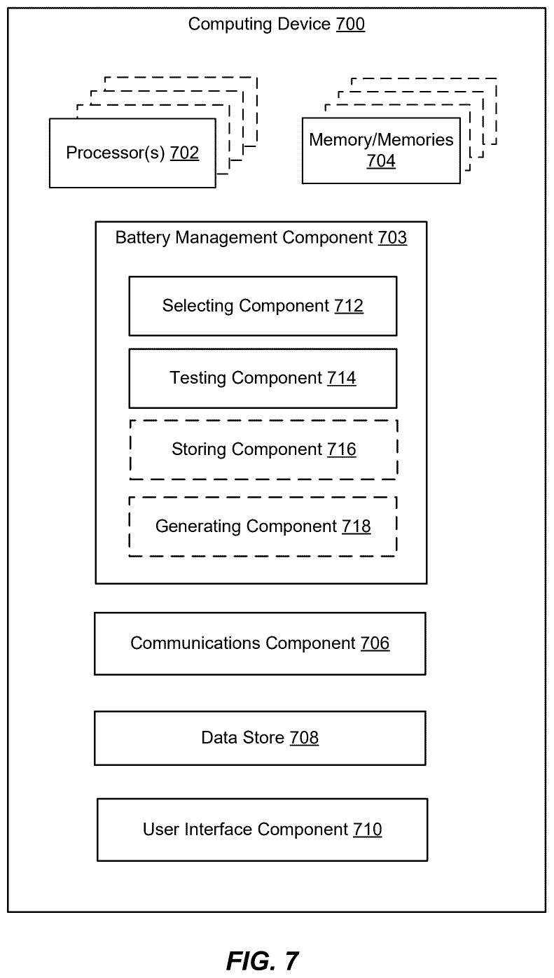

FIG. 5 is a flowchart of an example method 500 for battery testing. The method 500 may implement the functionality described herein with reference to FIGS. 1, 2, 3A-3D, and 4A-4C above or FIG. 7 below, and may be performed by one or more components of the control unit 102, the computing device 700, or any other component described herein with reference to FIGS. 1, 2, 3A-3D, and 4A-4C above or FIG. 7 below.

At 502, if a fire alarm event comes in or if the alternate current (AC) supply is lost at any point during the execution of the method 500, the active battery test of the method 500 is canceled, and the system reverts back to normal operation.

At 504, the method 500 compares the battery life with a recommended level. If the battery life is more than the recommended level, at 506 the method 500 indicates a failure and generates a notification to replace the battery. Accordingly, the battery is replaced after a certain amount of time (e.g., 5 years) even if the battery has passed previous tests. If the battery life is below the recommended level, at 508 the method 500 declares a supervisory trouble or equivalent that indicates that the system is in test. Accordingly, a user may be notified (e.g., via a blinking LED or a message) that the system is undergoing a test and may be disconnected from AC power.

At 510 the method 500 determines whether the system can make use of multiple batteries. If yes, then at 512 the method 500 determines to use a previously-depleted battery (e.g., 5-minute depleted) through this test as a load, and at 514 performs the battery test using this load. Such load may provide the most non-disruptive way for testing a battery, and also provides an energy-efficient way for testing a battery because power is used to replenish a depleted battery instead of being wasted on a load as heat.

Otherwise, at 516 the method 500 determines if the system uses a speaker. If yes, then at 518 the method 500 plays an inaudible frequency (e.g., 21 kHz) on the speaker and applies the speaker as a load on a per-circuit basis to measure the current for that circuit and saves the current in a table. Accordingly, the measurements may be used for determining the appropriate load for battery testing. Then, at 514 the method 500 performs the battery test using this load. In some non-limiting aspects, for example, a “circuit” refers to a “branch” of devices that are connected to a pair of wires that terminate at the control unit. For example, a circuit may include a number of speakers that are connected to a pair of wires and are located on a certain area of a building (e.g., located on the first floor of a building). In one example, the speakers in the circuit may be either all OFF or all ON, in which case at 518 the method 500 may enable the entire circuit, which enables all the speakers on the circuit. Alternatively, if a circuit includes individually-addressable devices, at 518 the method 500 may enable a subset of the circuit, where the subset includes one or more of the individually-addressable devices. For example, if a circuit of the first floor of a building includes an addressable speaker that is located in the garage, at 518 the method 500 may enable/turn on only the addressable speaker that is located in the garage.

If the system does not use a speaker, at 520 the method 500 determines if the system uses one or more horns. If yes, then at 522 the method 500 plays an inaudible frequency (e.g., 21 kHz) on the one or more horns (if possible), and applies the one or more horns as a load on a per-circuit basis to measure the current for that circuit and saves the current in a table. Then, at 514 the method 500 performs the battery test using this load.

If the system does not use horns, at 524 the method 500 determines if the system uses one or more strobes. If yes, then at 526 the method 500 applies the one or more strobes as a load on a per-circuit basis to measure the current for that circuit and saves the current in a table. Then, at 514 the method 500 performs the battery test using this load.

If the system does not use one or more strobes, at 525 the method 500 determines if the system uses a resistor for battery test. If yes, then at 527 the method 500 selects the resistor as a load for battery test. Then, at 514 the method 500 performs the battery test using this load. In some aspects, for example, the resistor may be manually insertable into the control unit or may be permanently built into the control unit.

If the system does not use a resistor, at 528 the method 500 generates a notification to do manual battery test.

In some aspects, more than one type of load may be used for battery testing, for example, if one type of load does not provide sufficient current draw for battery testing.

Referring to FIGS. 6A-6C, in one non-limiting example aspect, performing the battery test at block 514 of the method 500 may include the method 600.

Specifically, referring first to FIG. 6A, at 602 the method 600 includes measuring the battery charging circuit when AC power is on. This is to make sure that the battery is not pre-damaged and is fully charged. At 604 the method 600 determines whether the battery charging current is less than 20 mA, and if not, the method 600 goes back to 602. The battery needs to be in float and fully charged for the method 600 to proceed. If the battery charging current remains above 20 mA for a period of time (e.g., a number of hours), the method 600 indicates an error and does not run the battery test. This may happen if there has been a recent power outage and the battery is not fully charged, or if the battery is in fact damaged.

If the battery charging current is less than 20 mA, at 606 the method 600 measures and logs full battery voltage when AC power is on. At 608 the method 600 also measures and logs the cabinet temperature. The cabinet temperature may be used for temperature compensation for the chargers and/or for software-controlled battery charging. In some aspects, a standards body such as NFPA may also require comparing the battery temperature against the ambient temperature to determine if the battery is damaged. In some aspects, the cabinet temperature is read and reported alongside the battery test results.

At 610 the method 600 switches the control unit from AC power to battery on a per-battery/system basis, for example, to test multiple batteries at the same time, to test multiple batteries one by one, etc. In some aspects, for example, if there are two enclosures with two respective battery sets, the method 600 may decide whether to test all four batteries in a cascaded manner (which would be more reliable because only one enclosure is under test at a given time), or whether to run battery tests in the two enclosures at the same time (which would be faster). For example, a 3 hour test may deplete a battery by 20%, which is not desirable for sustaining the system if there is a subsequent power outage or a life safety event (e.g., a fire). Accordingly, a 3 hour test may be run on only one battery at a time, in order to ensure that the other batteries/cabinets are fully charged to sustain the system in case of a power outage or a life safety event.

At 612 the method 600 sets the system status to standby and measures and logs the battery current draw for a period of time (e.g., for a number of seconds). This includes disconnecting from the AC power and running the system on battery to determine whether the battery is large enough (has sufficient capacity) to sustain the system. Also, at 614 the method 600 sets the system status to full alarm load and measures and logs the battery current draw for a period of time (e.g., for a number of seconds). The measured currents will indicate whether the battery can sustain a desired alarm time. For example, if the standby current is 1.0 A and the desired standby time is 24 hours, then a battery with a capacity of at least 24.0 A-h is required. Accordingly, such validation/testing of battery capacity may be performed autonomously by the control unit, and does not require removing the battery by a technician and/or rebooting the system by a technician.

Continuing to FIG. 6B, at 616 the method 600 switches back to AC power and recharges the battery, for example, for 5-20 minutes. This is because the battery may have been at least partially depleted during the tests in the previous blocks of the method 600. At 618 the method 600 determines whether the battery charging current is less than 20 mA, and if not, the method 600 goes back to 616.

Once the battery charging current is less than 20 mA, at 620 the method 600 selectively enables loads to draw, for example, at a C-rate of ˜0.05 C of the battery capacity as measured on the battery voltage, for example, as measured/logged over various loads in the method 500. For example, based on previously-measured/logged voltages for loads such as speakers, horns, strobes, etc., the method 600 determines a load or a selection/combination of loads that can draw the appropriate current to discharge the battery for testing the battery.

At 622 the method 600 switches load sources and PSU/charger from AC power to battery use. At 624 the method 600 measures the battery current. At 626 the method 600 waits for a period of time (e.g., 5 minutes).

Continuing to FIG. 6C, at 628 the method 600 measures the battery voltage. At 630 the method 600 determines whether the battery voltage is greater than or equal a certain percentage (e.g., 85% or 20.4 V DC), and if not, at 632 the method 600 indicates failure and generates a notification to replace the battery. Otherwise, at 634 the method 600 switches the load sources and the PSU/charger back to AC power.

At 636 the method 600 measures the battery charging current. At 638 the method 600 recharges the battery for a period of time (e.g., 5-10 minutes). At 640 the method 600 determines whether the battery charging current is less than 20 mA, and if not, the method 600 goes back to 638. Otherwise, at 642 the method 600 reports battery test conclusion and puts the system back into normal operation.

Alternatively, the method 600 may skip recharging the battery at 638 and 640, and may instead use the battery as a load to test another battery, which would also at least partially recharge the already-tested battery.

FIG. 7 illustrates an example block diagram providing details of computing components in a computing device 700 that may implement all or a portion of the control unit 102 or any other component described with reference to FIGS. 1, 2, 3A-3D, 4A-4C, 5, and 6A-6C above. The computing device 700 includes one or more processors 702 which may be configured, individually or in combination, to execute or implement software, hardware, and/or firmware modules that perform any battery testing or other functionality described herein with reference to the control unit 102 or any other component described with reference to FIGS. 1, 2, 3A-3D, 4A-4C, 5, and 6A-6C above. In an aspect, for example, the one or more processors 702 may be configured, individually or in combination, to execute or implement a battery management component 703 that performs any battery testing or other functionality described herein with reference to the control unit 102 or any other component described with reference to FIGS. 1, 2, 3A-3D, 4A-4C, 5, and 6A-6C above.

The one or more processors 702 may be a micro-controller and/or may include a single or multiple set of processors or multi-core processors. Moreover, the one or more processors 702 may be implemented as an integrated processing system and/or a distributed processing system. The computing device 700 may further include one or more memories 704, such as for storing local versions of applications being executed by the one or more processors 702, related instructions, parameters, etc. The one or more memories 704 may include a type of memory usable by a computer, such as random access memory (RAM), read only memory (ROM), tapes, magnetic discs, optical discs, volatile memory, non-volatile memory, and any combination thereof. Additionally, the one or more processors 702 and the one or more memories 704 may include and execute an operating system executing on the one or more processors 702, one or more applications, display drivers, etc., and/or other components of the computing device 700.

As used herein, a processor, at least one processor, and/or one or more processors, individually or in combination, configured to perform or operable for performing a plurality of actions is meant to include at least two different processors able to perform different, overlapping or non-overlapping subsets of the plurality actions, or a single processor able to perform all of the plurality of actions. In one non-limiting example of multiple processors being able to perform different ones of the plurality of actions in combination, a description of a processor, at least one processor, and/or one or more processors configured or operable to perform actions X, Y, and Z may include at least a first processor configured or operable to perform a first subset of X, Y, and Z (e.g., to perform X) and at least a second processor configured or operable to perform a second subset of X, Y, and Z (e.g., to perform Y and Z). Alternatively, a first processor, a second processor, and a third processor may be respectively configured or operable to perform a respective one of actions X, Y, and Z. It should be understood that any combination of one or more processors each may be configured or operable to perform any one or any combination of a plurality of actions.

As used herein, a memory, at least one memory, and/or one or more memories, individually or in combination, configured to store or having stored thereon instructions executable by one or more processors for performing a plurality of actions is meant to include at least two different memories able to store different, overlapping or non-overlapping subsets of the instructions for performing different, overlapping or non-overlapping subsets of the plurality actions, or a single memory able to store the instructions for performing all of the plurality of actions. In one non-limiting example of one or more memories, individually or in combination, being able to store different subsets of the instructions for performing different ones of the plurality of actions, a description of a memory, at least one memory, and/or one or more memories configured or operable to store or having stored thereon instructions for performing actions X, Y, and Z may include at least a first memory configured or operable to store or having stored thereon a first subset of instructions for performing a first subset of X, Y, and Z (e.g., instructions to perform X) and at least a second memory configured or operable to store or having stored thereon a second subset of instructions for performing a second subset of X, Y, and Z (e.g., instructions to perform Y and Z). Alternatively, a first memory, and second memory, and a third memory may be respectively configured to store or have stored thereon a respective one of a first subset of instructions for performing X, a second subset of instruction for performing Y, and a third subset of instructions for performing Z. It should be understood that any combination of one or more memories each may be configured or operable to store or have stored thereon any one or any combination of instructions executable by one or more processors to perform any one or any combination of a plurality of actions. Moreover, one or more processors may each be coupled to at least one of the one or more memories and configured or operable to execute the instructions to perform the plurality of actions. For instance, in the above non-limiting example of the different subset of instructions for performing actions X, Y, and Z, a first processor may be coupled to a first memory storing instructions for performing action X, and at least a second processor may be coupled to at least a second memory storing instructions for performing actions Y and Z, and the first processor and the second processor may, in combination, execute the respective subset of instructions to accomplish performing actions X, Y, and Z. Alternatively, three processors may access one of three different memories each storing one of instructions for performing X, Y, or Z, and the three processor may in combination execute the respective subset of instruction to accomplish performing actions X, Y, and Z. Alternatively, a single processor may execute the instructions stored on a single memory, or distributed across multiple memories, to accomplish performing actions X, Y, and Z.

Further, the computing device 700 may include a communications component 706 that provides for establishing and maintaining communications with one or more other devices, parties, entities, etc. utilizing hardware, software, and services. The communications component 706 may carry communications between components on the computing device 700, as well as between the computing device 700 and external devices, such as devices located across a communications network and/or devices serially or locally connected to the computing device 700. For example, the communications component 706 may include one or more buses, and may further include transmit chain components and receive chain components associated with a wireless or wired transmitter and receiver, respectively, operable for interfacing with external devices.

Additionally, the computing device 700 may include a data store 708, which can be any suitable combination of hardware and/or software, that provides for mass storage of information, databases, and programs. For example, the data store 708 may be or may include a data repository for applications and/or related parameters not currently being executed by the one or more processors 702. In addition, the data store 708 may be a data repository for an operating system, application, display driver, etc., executing on the one or more processors 702, and/or one or more other components of the computing device 700.

The computing device 700 may also include a user interface component 710 operable to receive inputs from a user of the computing device 700 and further operable to generate outputs for presentation to the user (e.g., via a display interface to a display device). The user interface component 710 may include one or more input devices, including but not limited to a keyboard, a number pad, a mouse, a touch-sensitive display, a navigation key, a function key, a microphone, a voice recognition component, or any other mechanism capable of receiving an input from a user, or any combination thereof. Further, the user interface component 710 may include one or more output devices, including but not limited to a display interface, a speaker, a haptic feedback mechanism, a printer, any other mechanism capable of presenting an output to a user, or any combination thereof.

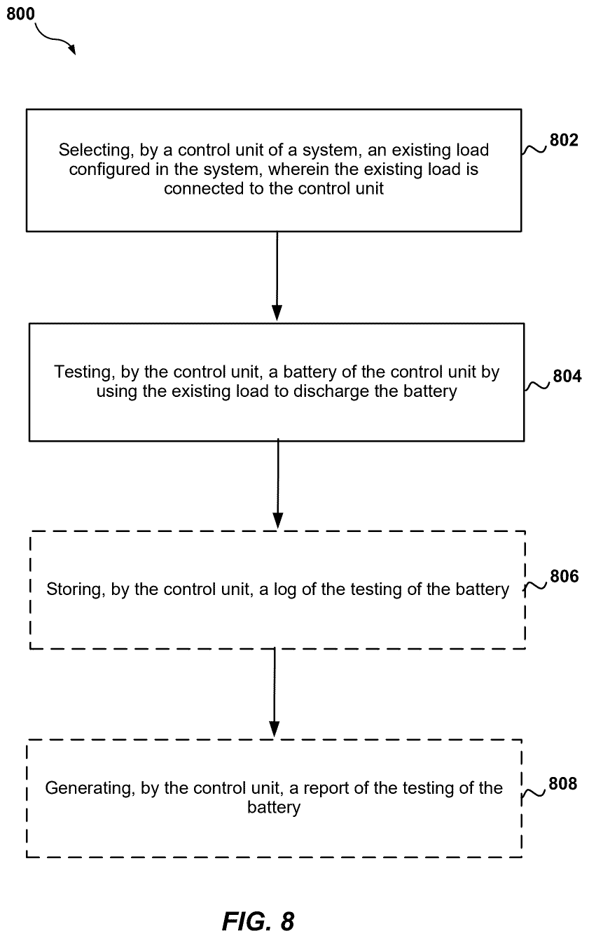

FIG. 8 is a flowchart of an example method 800 of battery testing. The method 800 may implement the functionality described herein with reference to FIGS. 1, 2, 3A-3D, 4A-4C, 5, 6A-6C, and 7 above, and may be performed by one or more components of the computing device 700, the control unit 102, or any other component described with reference to FIGS. 1, 2, 3A-3D, 4A-4C, 5, 6A-6C, and 7 above.

At 802, the method 800 includes selecting, by a control unit of a system, an existing load configured in the system, wherein the existing load is connected to the control unit. For example, in an aspect, the computing device 700, the control unit 102, and/or selecting component 712 of the battery management component 703 may be configured to or may comprise means for selecting, by a control unit of a system, an existing load configured in the system, wherein the existing load is connected to the control unit.

For example, referring to FIG. 1, the control unit 102 may select an existing load configured in the system 100, wherein the existing load is connected to the control unit 102.

At 804, the method 800 includes testing, by the control unit, a battery of the control unit by using the existing load to discharge the battery. For example, in an aspect, the computing device 700, the control unit 102, and/or testing component 714 of the battery management component 703 may be configured to or may comprise means for testing, by the control unit, a battery of the control unit by using the existing load to discharge the battery.

For example, the control unit 102 may test the battery 208 of the control unit 102 by using the existing load to discharge the battery 208.

In some implementations, the existing load comprises a device that is connected to the control unit and is addressable by and/or controllable by and/or powered by the control unit, such as the speaker 104, the notification appliance 106, the detector 108, etc.

In some implementations, the existing load comprises a built-in load configured within the control unit, such as the resistor 207.

In some implementations, the existing load comprises another battery that has been previously tested and at least partially discharged. For example, referring to FIG. 4C, the first battery 402 may be used as a load to test the second battery 404.

In some implementations, the testing is configured to recharge the another battery. For example, referring to FIG. 4C, using the first battery 402 as a load to test the second battery 404 also recharges the first battery 402.

In some implementations, the another battery is configured within the control unit or within another control unit of the system. For example, referring to FIG. 4C, the first battery 402 and the second battery 404 may be within a same control unit 102.

In some implementations, the existing load comprises a speaker or an audible notification appliance. For example, the first battery 402 and the second battery 404 may be in two separate control units that are in vicinity of each other or otherwise are connected to each other for cascaded battery testing.

In some implementations, testing the battery comprises using the battery to operate the speaker or the audible notification appliance at an inaudible frequency, such as a 21 KHz frequency.

In some implementations, the existing load comprises a visual notification appliance, such as a strobe.

In some implementations, testing the battery comprises supplying a continuous current to the visual notification appliance. For example, a strobe may be used as a load for battery testing and may be operated at a continuous low current to avoid disruptions.

In some implementations, testing the battery comprises operating the visual notification appliance at a dimmed state. For example, a strobe may be used as a load for battery testing and may be operated at a dimmed state to avoid disruptions.

In some implementations, testing the battery comprises using the existing load to discharge the battery at a pre-determined rate. For example, a strobe may be used as a load for battery testing after hours to avoid disruptions.

In some implementations, testing the battery comprises using the existing load to discharge the battery for a pre-determined period of time, for example, 5 minutes or 3 hours according to a battery testing standard.

In some implementations, the system comprises a fire alarm system, wherein the control unit comprises a fire alarm control unit.

Optionally, at 806 the method 800 may further comprise storing, by the control unit, a log of the testing of the battery. For example, in an aspect, the computing device 700, the control unit 102, and/or storing component 716 of the battery management component 703 may be configured to or may comprise means for storing, by the control unit, a log of the testing of the battery.

For example, the control unit 102 may store a log of the testing of the battery 208.

Optionally, at 808 the method 800 may further include generating, by the control unit, a report of the testing of the battery. For example, in an aspect, the computing device 700, the control unit 102, and/or generating component 718 of the battery management component 703 may be configured to or may comprise means for generating, by the control unit, a report of the testing of the battery.

For example, the control panel 102 may generate a report of the testing of the battery 208 and send the report to the workstation 110 to be uploaded to the cloud system 112.

In some implementations, selecting the existing load comprises selecting one or more devices configured to collectively draw a pre-determined amount of current from the battery, for example, as described herein with reference to block 620 of the method 600.

In some implementations, the pre-determined amount of current is configured for testing the battery by drawing the pre-determined amount of current over a pre-determined amount of time. For example, in one non-limiting aspect, the battery 208 may be discharged at a C-rate of 0.05 C for 5 minutes using a 21 KHz speaker load (e.g., to generate an inaudible and non-disruptive sound).

Some further example aspects are provided in the below clauses.
1. A method of battery testing, comprising:
selecting, by a control unit of a system, an existing load configured in the system, wherein the existing load is connected to the control unit; and
testing, by the control unit, a battery of the control unit by using the existing load to discharge the battery.
2. The method of clause 1, wherein the existing load comprises a device that is connected to the control unit and is addressable by and/or controllable by and/or powered by the control unit.
3. The method of clause 1 or 2, wherein the existing load comprises a built-in load configured within the control unit.
4. The method of any one of the above clauses, wherein the existing load comprises another battery that has been previously tested and at least partially discharged.
5. The method of clause 4, wherein the testing is configured to recharge the another battery.
6. The method of clause 4 or 5, wherein the another battery is configured within the control unit or within another control unit of the system.
7. The method of any one of the above clauses, wherein the existing load comprises a speaker or an audible notification appliance.
8. The method of clause 7, wherein testing the battery comprises using the battery to operate the speaker or the audible notification appliance at an inaudible frequency.
9. The method of any one of the above clauses, wherein the existing load comprises a visual notification appliance.
10. The method of clause 9, wherein testing the battery comprises supplying a continuous current to the visual notification appliance.
11. The method of clause 9 or 10, wherein testing the battery comprises operating the visual notification appliance at a dimmed state.
12. The method of any one of the above clauses, wherein testing the battery comprises using the existing load to discharge the battery at a pre-determined rate.
13. The method of any one of the above clauses, wherein testing the battery comprises using the existing load to discharge the battery for a pre-determined period of time.
14. The method of any one of the above clauses, wherein the system comprises a fire alarm system, wherein the control unit comprises a fire alarm control unit.
15. The method of any one of the above clauses, further comprising storing, by the control unit, a log of the testing of the battery.
16. The method of any one of the above clauses, further comprising generating, by the control unit, a report of the testing of the battery.
17. The method of any one of the above clauses, wherein selecting the existing load comprises selecting one or more devices configured to collectively draw a pre-determined amount of current from the battery.
18. The method of clause 17, wherein the pre-determined amount of current is configured for testing the battery by drawing the pre-determined amount of current over a pre-determined amount of time.
19. An apparatus for battery testing, comprising:
one or more processors; and
one or more memories communicatively coupled with the one or more processor and, individually or in combination, storing instructions that when executed by the one or more processors, cause the one or more processors, individually or in combination, to:
select, by a control unit of a system, an existing load configured in the system, wherein the existing load is connected to the control unit; and
test, by the control unit, a battery of the control unit by using the existing load to discharge the battery.
20. A computer-readable medium comprising instructions for battery testing, wherein the instructions, when executed by one or more processors, cause the one or more processors, individually or in combination, to:
select, by a control unit of a system, an existing load configured in the system, wherein the existing load is connected to the control unit; and
test, by the control unit, a battery of the control unit by using the existing load to discharge the battery.
21. An apparatus comprising:
one or more processors; and
one or more memories communicatively coupled with the one or more processors and, individually or in combination, storing instructions that when executed by the one or more processors, cause the one or more processors, individually or in combination, to perform the method of any one of clauses 1 to 18.
22. An apparatus comprising means for performing the method of any one of clauses 1 to 18.
23. A computer-readable medium storing instructions that, when executed by one or more processors, cause the one or more processors, individually or in combination, to perform the method of any one of clauses 1 to 18.
24. The computer-readable medium of clause 23, wherein the computer-readable medium is non-transitory.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

1-20. (canceled)

21. A method of battery testing, comprising:
selecting, by a control unit of a system, an existing load configured in the system, wherein the existing load is connected to the control unit and comprises:
a first battery configured in the system; or
a device that is addressable by the control unit; and
testing, by the control unit, a second battery of the control unit by using the existing load selected by the control unit to discharge the second battery.

22. The method of claim 21, wherein the device is controllable by and/or powered by the control unit.

23. The method of claim 21, wherein the first battery has been previously tested and at least partially discharged.

24. The method of claim 23, wherein the testing is configured to recharge the first battery.

25. The method of claim 21, wherein the first battery is configured within the control unit or within another control unit of the system.

26. The method of claim 21, wherein the device comprises a speaker or an audible notification appliance.

27. The method of claim 26, wherein testing the second battery comprises using the second battery to operate the speaker or the audible notification appliance at an inaudible frequency.

28. The method of claim 21, wherein the device comprises a visual notification appliance.

29. The method of claim 28, wherein testing the second battery comprises supplying a continuous current to the visual notification appliance.

30. The method of claim 28, wherein testing the second battery comprises operating the visual notification appliance at a dimmed state.

31. The method of claim 21, wherein testing the second battery comprises using the existing load to discharge the second battery at a pre-determined rate.

32. The method of claim 21, wherein testing the second battery comprises using the existing load to discharge the second battery for a pre-determined period of time.

33. The method of claim 21, wherein the system comprises a fire alarm system, wherein the control unit comprises a fire alarm control unit.

34. The method of claim 21, further comprising storing, by the control unit, a log of the testing of the second battery.

35. The method of claim 21, further comprising generating, by the control unit, a report of the testing of the second battery.

36. The method of claim 21, wherein selecting the existing load comprises selecting one or more devices configured to collectively draw a pre-determined amount of current from the second battery.

37. The method of claim 36, wherein the pre-determined amount of current is configured for testing the second battery by drawing the pre-determined amount of current over a pre-determined amount of time.

38. An apparatus for battery testing, comprising:
one or more processors; and
one or more memories communicatively coupled with the one or more processors and, individually or in combination, storing instructions that when executed by the one or more processors, individually or in combination, cause the one or more processors to:
select, by a control unit of a system, an existing load configured in the system, wherein the existing load is connected to the control unit and comprises:
a first battery configured in the system; or
a device that is addressable by the control unit; and
testing, by the control unit, a second battery of the control unit by using the existing load selected by the control unit to discharge the second battery.

39. The apparatus of claim 38, wherein testing the second battery comprises using the existing load to discharge the second battery at a pre-determined rate and/or for a pre-determined period of time.

40. One or more computer-readable media comprising instructions for battery testing, wherein the instructions, when executed by one or more processors, individually or in combination, cause the one or more processors to:
select, by a control unit of a system, an existing load configured in the system, wherein the existing load is connected to the control unit and comprises:
a first battery configured in the system; or
a device that is addressable by the control unit; and
test, by the control unit, a second battery of the control unit by using the existing load selected by the control unit to discharge the second battery.
